(19) United States
(12) Patent Application Publication
(10) Pub. No.: US 2018/0053868 A1
(43) Pub. Date: Feb. 22, 2018

(54) PHOTOELECTRIC CONVERSION DEVICE HAVING REFLECTION PLATE

(71) Applicant: SUMITOMO CHEMICAL COMPANY, LIMITED, Tokyo (JP)

(72) Inventor: Kouichi ROKUHARA, Tsukuba-shi (JP)

(73) Assignee: SUMITOMO CHEMICAL COMPANY, LIMITED, Tokyo (JP)

(21) Appl. No.: 15/557,856

(22) PCT Filed: Mar. 15, 2016
(86) PCT No.: PCT/JP2016/058061

§ 371 Date: Sep. 13, 2017

(30) Foreign Application Priority Data
Mar. 18, 2015 (JP) 2015-054350

(51) Int. Cl. H01L 31/054; H01L 51/44; H01L 27/30

(52) U.S. Cl. CPC H01L 31/054; H01L 27/301; H01L 51/441

(57) ABSTRACT

A photoelectric conversion device comprising a supporting substrate, an electrode, an active layer, an electrode and a reflection plate laminated in this order and giving an average transmittance of 10% or more of light in a wavelength range of from 400 to 700 nm, wherein the reflection plate has an average transmittance of 70% or more of light in a wavelength range of from 400 to 700 nm and the active layer has an average reflectance of 50% or more of light in a region of ±150 nm of the light absorption peak wavelength.

### TECHNICAL FIELD

The present invention relates to a photoelectric conversion device having a reflection plate.

### BACKGROUND ART

Recently, adoption of a solar system using a pn junction type silicon-based solar battery as one embodiment of the photoelectric conversion device is suggested. However, the silicon-based solar battery is opaque and restricted in the use in various lifestyles including design.

In contrast, organic film solar batteries having an active layer containing an organic compound such as a polymer compound and the like have wide choice of device constitution and also a transparent solar battery can be fabricated. Therefore, organic film solar batteries are gaining attention as a novel technology capable of responding to various needs depending on use environments. For example, an organic film solar battery comprising a substrate, an electrode, a hole transporting layer, an active layer containing a polymer compound, a functional layer and an electrode laminated in this order is known (Patent document 1).

### PRIOR ART DOCUMENT

### Patent Document

[Patent document 1] JP-A No. 2013-33906

### SUMMARY OF THE INVENTION

The organic film solar battery described in Patent document 1 does not necessarily obtain sufficient photoelectric conversion efficiency in some cases.

The present invention is as described below.

[1] A photoelectric conversion device comprising a supporting substrate, an electrode, an active layer, an electrode and a reflection plate laminated in this order and having an average transmittance of 10% or more of light in a wavelength range of from 400 to 700 nm, wherein the reflection plate has an average transmittance of 70% or more of light in a wavelength range of from 400 to 700 nm and the active layer has an average reflectance of 50% or more of light in a region of ±150 nm of the light absorption peak wavelength.

[2] The photoelectric conversion device according to [1], wherein the reflection plate further has an average reflectance of 50% or more of light in a wavelength range of from 850 to 1100 nm.

[3] The photoelectric conversion device according to [1] or [2], wherein the active layer contains a polymer compound.

[4] The photoelectric conversion device according to [3], wherein the active layer containing the polymer compound has a light absorption peak wavelength of 750 to 850 nm.

[5] The photoelectric conversion device according to [3] or [4], wherein the polymer compound is a polymer compound comprising a constitutional unit represented by the formula

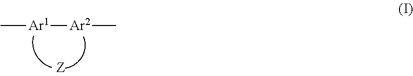

### (I):

[in the formula (I), Z represents a group represented by any one of the following formulae (Z-1) to (Z-7). Ar¹ and Ar² may be the same or different and represent a trivalent aromatic heterocyclic group.]

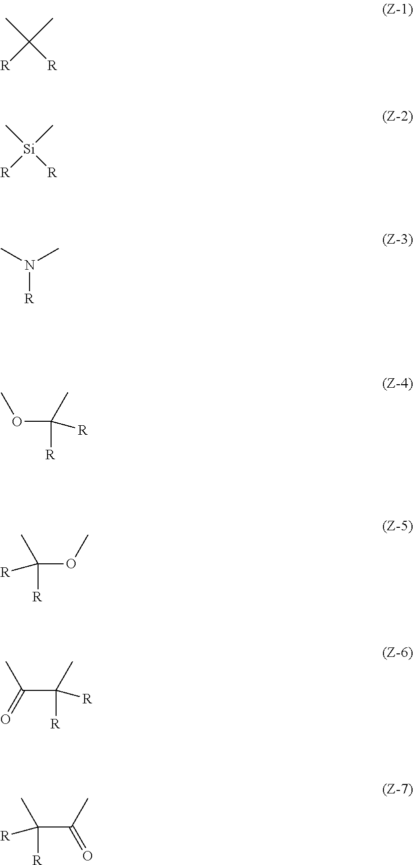

[in the formula (Z-1) to the formula (Z-7), R represents a hydrogen atom, a halogen atom, an amino group, a cyano group or a monovalent organic group. When two R are present, they may be the same or different.].

[6] The photoelectric conversion device according to [5], wherein the constitutional unit represented by the formula (I) is a constitutional unit represented by the following formula (II):

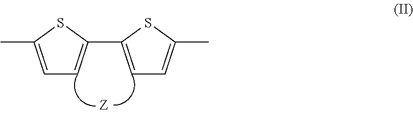

[in the formula (II), Z represents the same meaning as described above.].

[7] The photoelectric conversion device according to [5] or [6], wherein Z is a group represented by any one of the formulae (Z-4) to (Z-7).

[8] The photoelectric conversion device according to any one of [5] to [7], wherein the constitutional unit represented by the formula (I) is a constitutional unit represented by the

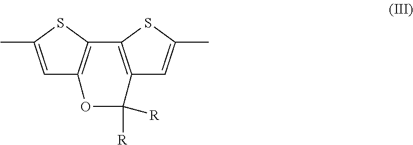

following formula (III):
(in the formula (III), two R may be the same or different and represent the same meaning as described above.].

[9] A solar battery module comprising the photoelectric conversion device according to any one of [1] to [8].

### BRIEF EXPLANATION OF DRAWINGS

FIG. 1 is a transmission spectrum of an IR cut filter.

FIG. 2 is a reflection spectrum of an IR cut filter.

### MODES FOR CARRYING OUT THE INVENTION

The present invention will be illustrated in detail below.

### <1> Constitution of Photoelectric Conversion Device

The photoelectric conversion device of the present invention is

a photoelectric conversion device comprising a supporting substrate, an electrode (first electrode), an active layer, an electrode (second electrode) and a reflection plate laminated in this order and having an average transmittance of 10% or more of light in a wavelength range of from 400 to 700 nm, wherein the above-described reflection plate has an average transmittance of 70% or more of light in a wavelength range of from 400 to 700 nm and the active layer has an average reflectance of 50% or more of light in a region of ±150 nm of the light absorption peak wavelength.

The photoelectric conversion device of the present invention is preferably an organic photoelectric conversion device. The organic photoelectric conversion device denotes a photoelectric conversion device containing an organic compound in an active layer.

The photoelectric conversion device of the present invention includes (a) a photoelectric conversion device in which the first electrode is an anode and the second electrode is a cathode and (b) a photoelectric conversion device in which the first electrode is a cathode and the second electrode is an anode.

The photoelectric conversion device of the present invention includes a photoelectric conversion device having a constitution in which an anode, an active layer, a cathode and a sealing substrate are laminated in this order on a supporting substrate and a reflection plate is pasted.

The photoelectric conversion device of the present invention includes also a photoelectric conversion device having a constitution in which a cathode, an active layer, an anode and a sealing substrate are laminated in this order on a supporting substrate and a reflection plate is pasted.

It is preferable that an anode and a cathode are constituted of a transparent or semi-transparent electrode. Incident light from a transparent or semi-transparent electrode is absorbed by at least one compound selected from the group consisting of electron accepting compounds and electron donating compounds described later in an active layer, thereby generating an exciton composed of an electron and a hole bonded. When this exciton travels in the active layer and reaches the heterojunction interface where the electron accepting compound and the electron donating compound are adjacent, electrons and holes separate due to differences of respective HOMO energies and LUMO energies at the interface and independently movable charges (electrons and holes) are generated. The generated charges move to respective electrodes and are taken out outside as electric energy (current).

The photoelectric conversion device of the present invention has transparency. Specifically, the photoelectric conversion device of the present invention has an average transmittance of 10% or more of light in a wavelength range of from 400 to 700 nm. The average transmittance of light in a wavelength range of from 400 to 700 nm is preferably 20% or more from the standpoint of design, and more preferably 30% or more, further preferably 40% or more, particularly preferably 45% or more.

### (Supporting Substrate)

The photoelectric conversion device of the present invention is usually formed on a supporting substrate. As the supporting substrate, one which does not chemically change in fabricating a photoelectric conversion device is suitably used. As the supporting substrate, for example, a glass substrate, a plastic substrate, a polymer film and the like are listed, and as the supporting substrate, a highly light-permeable substrate is suitably used.

In the photoelectric conversion device of the present invention, light is usually incorporated from the side of a supporting substrate.

### (Anode)

As the anode, an electrically conductive metal oxide film, a metal film, an electrically conductive film containing an organic substance, and the like are used. Specifically, films of indium oxide, zinc oxide, tin oxide, indium tin oxide (abbreviated as ITO), indium zinc oxide (abbreviated as IZO), gold, platinum, silver, copper, aluminum, polyaniline and derivatives thereof, polythiophene and derivatives thereof, and the like are used. Of them, films of ITO, IZO and tin oxide are suitably used as the anode. For example, a transparent or semitransparent electrode obtained by adjusting the thickness of the above-described film constituting the anode to a thickness around which light can pass is used as the anode.

### (Active Layer)

The active layer can take the form of a single layer or the form of a laminate of a plurality of layers. The active layer having a constitution of a single layer is constituted of a layer containing an electron accepting compound and an electron donating compound.

The active layer having a constitution of a laminate of a plurality of layers is constituted, for example, of a laminate obtained by laminating a first active layer containing an electron donating compound and a second active layer containing an electron accepting compound. In this case, the first active layer is placed closer to an anode than the second active layer.

It is preferable that the active layer is formed by an application method. It is preferable that the active layer contains a polymer compound, and a polymer compound may be contained singly or two or more polymer compounds may be contained in combination. For enhancing the charge transportability of the active layer, at least one compound selected from the group consisting of electron donating compounds and electron accepting compounds may be mixed in the active layer.

The electron accepting compound used in a photoelectric conversion device is preferably a compound having its HOMO energy higher than the HOMO energy of an electron donating compound and having its LUMO energy higher than the LUMO energy of an electron donating compound.

The electron donating compound maybe a low molecular weight compound or a polymer compound. The low molecular weight electron donating compound includes phthalocyanine, metallophthalocyanine, porphyrin, metalloporphyrin, oligothiophene, tetracene, pentacene, rubrene and the like.

The polymer electron donating compound includes polyvinylcarbazole and derivatives thereof, polysilane and derivatives thereof, polysiloxane derivatives comprising an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, polymer compounds comprising a constitutional unit represented by the formula (I), and the like, and polymer compounds comprising a constitutional unit represented by the formula (I) are preferable.

These polymer compounds are preferably conjugated polymer compounds.

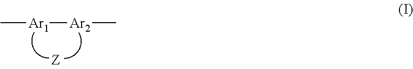

(in the formula (I), Ar¹ and Ar² may be the same or different and represent a trivalent aromatic heterocyclic group.).

In the formula (I), Z represents a group represented by any one of the following formulae (Z-1) to (Z-7).

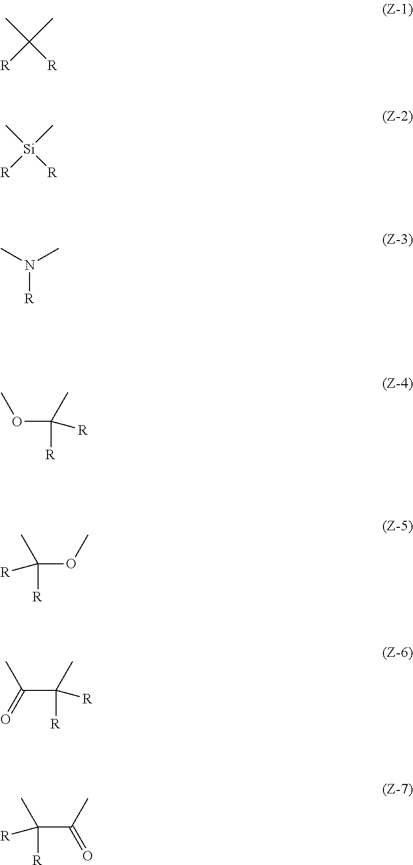

In the formula (Z-1) to the formula (Z-7), R represents a hydrogen atom, a halogen atom, an amino group, a cyano group or a monovalent organic group. The monovalent organic group includes, for example, an optionally substituted alkyl group, an optionally substituted alkoxy group, an optionally substituted alkylthio group, an aryl group, an aryloxy group, an arylthio group, an optionally substituted arylalkyl group, an optionally substituted arylalkoxy group, an optionally substituted arylalkylthio group, an optionally substituted acyl group, an optionally substituted acyloxy group, an optionally substituted amide group, an optionally substituted acid imide group, a substituted amino group, a substituted silyl group, a substituted silyloxy group, a substituted silylthio group, a substituted silylamino group, a monovalent heterocyclic group, a heterocyclicoxy group, a heterocyclicthio group, an arylalkenyl group, an arylalkynyl group and a substituted carboxyl group. In each of the formula (Z-1) to the formula (Z-7), when two R are present, they may be the same or different.

The halogen atom represented by R includes a fluorine atom, a chlorine atom, a bromine atom and an iodine atom, and a fluorine atom is preferable.

The optionally substituted alkyl group may be linear or branched, and may also be a cycloalkyl group. The alkyl group has a number of carbon atoms of usually 1 to 30. The substituent which the alkyl group optionally has includes, for example, a halogen atom. Specific examples of the halogen atom are the same as specific examples of the halogen atom represented by R. Specific examples of the optionally substituted alkyl group include linear alkyl groups such as a methyl group, an ethyl group, a propyl group, an isopropyl group, a butyl group, an isobutyl group, a sec-butyl group, a tert-butyl group, a pentyl group, an isopentyl group, a 2-methylbutyl group, a 1-methylbutyl group, a hexyl group, an isohexyl group, a 3-methylpentyl group, a 2-methylpentyl group, a 1-methylpentyl group, a heptyl group, an octyl group, an isooctyl group, a 2-ethylhexyl group, a 3,7-dimethyloctyl group, a nonyl group, a decyl group, an undecyl group, a dodecyl group, a tetradecyl group, a hexadecyl group, an octadecyl group, an eicosyl group and the like, and cycloalkyl groups such as a cyclopentyl group, a cyclohexyl group, an adamantyl group and the like.

The optionally substituted alkoxy group may be linear or branched, and may also be a cycloalkoxy group. The substituent which the alkoxy group optionally has includes, for example, a halogen atom. Specific examples of the halogen atom are the same as specific examples of the halogen atom represented by R. The alkoxy group has a number of carbon atoms of usually about 1 to 20. Specific examples of the optionally substituted alkoxy group include a methoxy group, an ethoxy group, a propoxy group, an isopropoxy group, a butoxy group, an isobutoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a lauryloxy group, a trifluoromethoxy group, a pentafluoroethoxy group, a perfluorobutoxy group, a perfluorohexyloxy group, a perfluorooctyloxy group, a methoxymethyloxy group and a 2-methoxyethyloxy group.

The optionally substituted alkylthio group may be linear or branched, and may also be a cycloalkylthio group. The substituent which the alkylthio group optionally has includes, for example, a halogen atom. Specific examples of the halogen atom are the same as specific examples of the halogen atom represented by R. The alkylthio group has a number of carbon atoms of usually about 1 to 20. Specific examples of the optionally substituted alkylthio group include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group and a trifluoromethylthio group.

The aryl group is an atomic group obtained by removing from an optionally substituted aromatic hydrocarbon one hydrogen atom on the aromatic ring and has a number of carbon atoms of usually 6 to 60. The substituent includes, for example, a halogen atom, an optionally substituted alkoxy group and an optionally substituted alkylthio group. Specific examples of the halogen atom, the optionally substituted alkoxy group and the optionally substituted alkylthio group are the same as specific examples of the halogen atom, the optionally substituted alkyl group, the optionally substituted alkoxy group and the optionally substituted alkylthio group represented by R. Specific examples of the aryl group include a phenyl group, C1 to C12 alkyloxyphenyl groups (The C1 to C12 alkyl denotes an alkyl having a number of carbon atoms of 1 to 12. The C1 to C12 alkyl is preferably a C1 to C8 alkyl, more preferably a C1 to C6 alkyl. The C1 to C8 alkyl denotes an alkyl having a number of carbon atoms of 1 to 8, and the C1 to C6 alkyl denotes an alkyl having a number of carbon atoms of 1 to 6. Specific examples of the C1 to C12 alkyl, the C1 to C8 alkyl and the C1 to C6 alkyl include those explained and exemplified for the above-described alkyl group. The same shall apply hereinafter.), C1 to C12 alkylphenyl groups, a 1-naphthyl group, a 2-naphthyl group and a pentafluorophenyl group.

The aryloxy group has a number of carbon atoms of usually about 6 to 60. Specific examples of the aryloxy group include a phenoxy group, C1 to C12 alkyloxyphenoxy groups, C1 to C12 alkylphenoxy groups, a 1-naphthyloxy group, a 2-naphthyloxy group and a pentafluorophenyloxy group.

The arylthio group has a number of carbon atoms of usually about 6 to 60. Specific examples of the arylthio group include a phenylthio group, C1 to C12 alkyloxyphenylthio groups, C1 to C12 alkylphenylthio groups, a 1-naphthylthio group, a 2-naphthylthio group and a pentafluorophenylthio group.

The optionally substituted arylalkyl group has a number of carbon atoms of usually about 7 to 60, and the alkyl portion optionally has a substituent. The substituent includes, for example, a halogen atom. Specific examples of the halogen atom are the same as specific examples of the halogen atom represented by R. Specific examples of the optionally substituted arylalkyl group include phenyl C1 to C12 alkyl groups, C1 to C12 alkyloxyphenyl C1 to C12 alkyl groups, C1 to C12 alkylphenyl C1 to C12 alkyl groups, 1-naphthyl-C1 to C12 alkyl groups and 2-naphthyl-C1 to C12 alkyl groups.

The optionally substituted arylalkoxy group has a number of carbon atoms of usually about 7 to 60, and the alkoxy portion optionally has a substituent. The substituent includes, for example, a halogen atom. Specific examples of the halogen atom are the same as specific examples of the halogen atom represented by R. Specific examples of the optionally substituted arylalkoxy group include phenyl C1 to C12 alkoxy groups, C1 to C12 alkoxyphenyl C1 to C12 alkoxy groups, C1 to C12 alkylphenyl C1 to C12 alkoxy groups, 1-naphthyl-C1 to C12 alkoxy groups and 2-naphthyl-C1 to C12 alkoxy groups.

The optionally substituted arylalkylthio group has a number of carbon atoms of usually about 7 to 60, and the alkylthio portion optionally has a substituent. The substituent includes, for example, a halogen atom. Specific examples of the halogen atom are the same as specific examples of the halogen atom represented by R. Specific examples of the optionally substituted arylalkylthio group include phenyl C1 to C12 alkylthio groups, C1 to C12 alkyloxyphenyl C1 to C12 alkylthio groups, C1 to C12 alkylphenyl C1 to C12 alkylthio groups, 1-naphthyl-C1 to C12 alkylthio groups and 2-naphthyl-C1 to C12 alkylthio groups.

The optionally substituted acyl group has a number of carbon atoms of usually about 2 to 20. The substituent which the acyl group optionally has includes, for example, a halogen atom. Specific examples of the halogen atom are the same as specific examples of the halogen atom represented by R. Specific examples of the optionally substituted acyl group include an acetyl group, a propionyl group, a butyryl group, an isobutyryl group, a pivaloyl group, a benzoyl group, a trifluoroacetyl group and a pentafluorobenzoyl group.

The optionally substituted acyloxy group has a number of carbon atoms of usually about 2 to 20. The substituent which the acyloxy group optionally has includes, for example, a halogen atom. Specific examples of the halogen atom are the same as specific examples of the halogen atom represented by R. Specific examples of the optionally substituted acyloxy group include an acetoxy group, a propionyloxy group, a butyryloxy group, an isobutyryloxy group, a pivaloyloxy group, a benzoyloxy group, a trifluoroacetyloxy group and a pentafluorobenzoyloxy group.

The optionally substituted amide group has a number of carbon atoms of usually about 1 to 20. The amide group denotes a group obtained by removing from an amide a hydrogen atom bonding to the nitrogen atom. The substituent which the amide group optionally has includes, for example, a halogen atom. Specific examples of the halogen atom are the same as specific examples of the halogen atom represented by R. Specific examples of the optionally substituted amide group include a formamide group, an acetamide group, a propioamide group, a butyramide group, a benzamide group, a trifluoroacetamide group, a pentafluorobenzamide group, a diformamide group, a diacetamide group, a dipropioamide group, a dibutyramide group, a dibenzamide group, a ditrifluoroacetamide group and a dipentafluorobenzamide group.

The optionally substituted acid imide group has a number of carbon atoms of usually about 2 to 20. The acid imide group denotes a group obtained by removing from an acid imide a hydrogen atom bonding to the nitrogen atom. The substituent which the acid imide group optionally has includes, for example, a halogen atom. Specific examples of the halogen atom are the same as specific examples of the halogen atom represented by R. Specific examples of the optionally substituted acid imide group include a succinimide group and a phthalic imide group.

The substituted amino group has a number of carbon atoms of usually about 1 to 40. The substituent which the substituted amino group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted amino group include a methylamino group, a dimethylamino group, an ethylamino group, a diethylamino group, a propylamino group, a dipropylamino group, an isopropylamino group, a diisopropylamino group, a butylamino group, an isobutylamino group, a tert-butylamino group, a pentylamino group, a hexylamino group, a cyclohexylamino group, a heptylamino group, an octylamino group, a 2-ethylhexylamino group, a nonylamino group, a decylamino group, a 3,7-dimethyloctylamino group, a laurylamino group, a cyclopentylamino group, a dicyclopentylamino group, a cyclohexylamino group, a dicyclohexylamino group, a pyrrolidyl group, a piperidyl group, a ditrifluoromethylamino group, a phenylamino group, a diphenylamino group, C1 to C12 alkyloxyphenylaroino groups, di(C1 to C12 alkyloxyphenyl) amino groups, di(C1 to C12 alkylphenyl)amino groups, a 1-naphthylamino group, a 2-naphthylamino group, a pentafluorophenylamino group, a pyridylamino group, a pyridazinylamino group, a pyrimidylamino group, a pyrazylamino group, a triazylamino group, phenyl C1 to C12 alkylamino groups, C1 to C12 alkyloxyphenyl C1 to C12 alkylamino groups, C1 to C12 alkylphenyl C1 to C12 alkylamino groups, di(C1 to C12 alkyloxyphenyl C1 to C12 alkyl)amino groups, di(C1 to C12 alkylphenyl C1 to C12 alkyl) amino groups, 1-naphthyl-C1 to C12 alkylamino groups and 2-naphthyl-C1 to C12 alkylamino groups.

The substituted silyl group has a number of carbon atoms of usually about 3 to 40. The substituent which the substituted silyl group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silyl group include a trimethylsilyl group, a triethylsilyl group, a tripropylsilyl group, a triisopropylsilyl group, a tert-butyldimethylsilyl group, a triphenylsilyl group, a tri-p-xylylsilyl group, a tribenzylsilyl group, a diphenylmethylsilyl group, a tert-butyldiphenylsilyl group and a dimethylphenylsilyl group.

The substituted silyloxy group has a number of carbon atoms of usually about 3 to 40. The substituent winch the substituted silyloxy group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silyloxy group include a trimethylsilyloxy group, a triethylsilyloxy group, a tripropylsilyloxy group, a triisopropylsilyloxy group, a tert-butyldimethylsilyloxy group, a triphenylsilyloxy group, a tri-p-xylylsilyloxy group, a tribenzylsilyloxy group, a diphenylmethylsilyloxy group, a tert-butyldiphenylsilyloxy group and a dimethylphenylsilyloxy group.

The substituted silylthio group has a number of carbon atoms of usually about 3 to 40. The substituent which the substituted silylthio group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silylthio group include a trimethylsilylthio group, a triethylsilylthio group, a tripropylsilylthio group, a triisopropylsilylthio group, a tert-butyldimethylsilylthio group, a triphenylsilylthio group, a tri-p-xylylsilylthio group, a tribenzylsilylthio group, a diphenylmethylsilylthio group, a tert-butyldiphenylsilylthio group and a dimethylphenylsilylthio group.

The substituted silylamino group has a number of carbon atoms of usually about 3 to 80. The substituent which the substituted silylamino group has includes, for example, an optionally substituted alkyl group and an aryl group. Specific examples of the optionally substituted alkyl group and the aryl group are the same as specific examples of the optionally substituted alkyl group and the aryl group represented by R. Specific examples of the substituted silylamino group include a trimethylsilylamino group, a triethylsilylamino group, a tripropylsilylamino group, a triisopropylsilylamino group, a tert-butyldimethylsilylamino group, a triphenylsilylamino group, a tri-p-xylylsilylamino group, a tribenzylsilylamino group, a diphenylmethylsilylamino group, a tert-butyldiphenylsilylamino group, a dimethylphenylsilylamlno group, a di(trimethylsilyl)amino group, a di(triethylsilyl)amino group, a di(tripropylsilyl)amino group, a di(triisopropylsilyl)amino group, a di(tert-butyldimethylsilyl)amino group, a di(triphenylsilyl)amino group, a di(tri-p-xylylsilyl)amino group, a di(tribenzylsilyl)amino group, a di(diphenylmethylsilyl)amino group, a di(tert-butyldiphenylsilyl)amino group and a di(dimethylphenylsilyljamino group.

The monovalent heterocyclic group is an atomic group obtained by removing from an optionally substituted heterocyclic compound one hydrogen atom on the heterocyclic ring. The monovalent heterocyclic group has a number of carbon atoms of usually 4 to 20. The heterocyclic compound includes, for example, furan, thiophene, pyrrole, pyrroline, pyrrolidine, oxazole, isooxazole, thiazole, isothiazole, imidazole, imidazoline, imidazolidine, pyrazole, pyrazoline, pyrazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene. chromane, isochromane, benzopyran, quinoline, isoquinoline, quinolizine, benzoimidazole, benzothiazole, indazole, naphthyridine, quinoxaline, quinazoline, quinazolidine, cinnoline, phthalazine, purine, pteridine, carbazole, xanthene, phenanthridine, acridine, β-carboline, perimidine, phenanthroline, thianthrene, phenoxathiin, phenoxazine, phenothiazine and phenazine. The substituent which the heterocyclic compound optionally has includes, for example, a halogen atom, an optionally substituted alkyl group, an optionally substituted alkoxy group and an optionally substituted alkylthio group. Specific examples of the halogen atom, the optionally substituted alkyl group, the optionally substituted alkoxy group and the optionally substituted alkylthio group are the same as specific examples of the halogen atom, the optionally substituted alkyl group, the optionally substituted alkoxy group and the optionally substituted alkylthio group represented by R. The heterocyclic group is preferably an aromatic heterocyclic group.

The heterocyclicoxy group includes a group represented by the formula (A-1) obtained by bonding of an oxygen atom to the above-described monovalent heterocyclic group. Specific examples of the heterocyclicoxy group include a thienyloxy group, C1 to C12 alkylthienyloxy groups, a pyrrolyloxy group, a furyloxy group, a pyridyloxy group, C1 to C12 alkylpyridyloxy groups, an imidazolyloxy group, a pyrazolyloxy group, a triazolyloxy group, an oxazolyloxy group, a thiazoleoxy group and a thiadiazoleoxy group.

The heterocyclicthio group includes a group represented by the formula (A-2) obtained by bonding of a sulfur atom to the above-described monovalent heterocyclic group. Specific examples of the heterocyclicthio group include a thienylmercapto group, C1 to C12 alkylthienylmercapto groups, a pyrrolylmercapto group, a furylmercapto group, a pyridylmercapto group, C1 to C12 alkylpyridylmercapto groups, an imidazolylmercapto group, a pyrazolylraercapto group, a triazolylmercapto group, an oxazolylmercapto group, a thiazolemercapto group and a thiadiazolemercapto group.

Ar³—O— (A-1)

Ar³—S— (A-2)

(in the formula (A-1) and the formula (A-2), Ar³ represents a monovalent heterocyclic group.).

The arylalkenyl group usually has a number of carbon atoms of 8 to 20. Specific examples of the arylalkenyl group include a styryl group.

The 0 0 0 1 arylalkynyl group usually has a number of carbon acorns of 8 to 20. Specific examples of the arylalkynyl group include a phenylacetylenyl group.

The substituted carboxyl group denotes a carboxyl group substituted with an alkyl group, an aryl group, an arylalkyl group or a monovalent heterocyclic group, and has a number of carbon atoms of usually about 2 to 60, preferably 2 to 48.

Specific examples of the substituted carboxyl group include a methoxycarbonyl group, an ethoxycarbonyl group, a propoxycarbonyl group, an isopropoxycarbonyl group, a butoxycarbonyl group, an isobutoxycarbonyl group, a t-butoxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenoxycarbonyl group, a naphthoxycarbonyl group, a pyridyloxycarbonyl group, and the like.

From the standpoint of enhancing solubility of a polymer compound having a constitutional unit represented by the formula (I) in a solvent, R is preferably an optionally substituted alkyl group having a number of carbon atoms of 6 or more, an optionally substituted alkoxy group having a number of carbon atoms of 6 or more, an optionally substituted alkylthio group having a number of carbon atoms of 6 or more, an optionally substituted aryl group, an optionally substituted aryloxy group, an optionally substituted arylthio group, an optionally substituted arylalkyl group, an optionally substituted arylalkoxy group, an optionally substituted arylalkylthio group, an optionally substituted acyl group having a number of carbon atoms of 6 or more or an optionally substituted acyloxy group having a number of carbon atoms of 6 or more, more preferably an optionally substituted alkyl group having a number of carbon atoms of 6 or more, an optionally substituted alkoxy group having a number of carbon atoms of 6 or more, an optionally substituted aryl group or an optionally substituted aryloxy group, particularly preferably an optionally substituted alkyl group having a number of carbon atoms of 6 or more.

The alkyl group having a number of carbon atoms of 6 or more as one preferable embodiment of R includes linear alkyl groups such as a hexyl group, a heptyl group, an octyl group, a nonyl group, decyl group, an undecyl group, a dodecyl group, a tridecyl group, a cecradecyl group, a pentadecyl group, a hexadecyl group, a heptadecyl group, an octadecyl group, a nonadecyl group, an icosyl group, a triacontyl group, a tetracontyl group, a pentacontyl group, and the like, and branched alkyl groups such as a 1,1,3,3-tetramethylbutyl group, a 1-methylheptyl group, a 2-ethylhexyl group, a 3,7-dimethyloctyl group, a 1-propylpentyl group, a 3-heptyldodecyl group, a 2-heptylundecyl group, a 2-octyldodecyl group, a 3,7,11-trimethyldodecyl group, a 3,7,11,15-tetramethylhexadecyl group, a 3,5,5-trimethylhexyl group, and the like.

The alkyl group having a number of carbon atoms of 6 or more is selected appropriately in view of solubility of a polymer compound in a solvent and the like, and is preferably a hexyl group, a heptyl group, an octyl group, a nonyl group, a decyl group, an undecyl group, a dodecyl group, a tridecyl group, a tetradecyl group, a pentadecyl group, a hexadecyl group, a 2-ethylhexyl group, a 3,7-dimethyloctyl group, a 1-propylpentyl group or a 3-heptyldodecyl group, more preferably a hexyl group, a heptyl group, an octyl group, a dodecyl group, a tetradecyl group, a hexadecyl group, a 2-ethylhexyl group, a 3,7-dimethyloctyl group or a 3-heptyldodecyl group, particularly preferably a hexyl group, an octyl group, a dodecyl group, a hexadecyl group, a 2-ethylhexyl group, a 3,7-dimethyloctyl group or a 3-heptyldodecyl group.

The aryl group as one preferable embodiment of R is preferably a phenyl group substituted with an alkyl group, when solubility of the polymer compound of the present invention in a solvent and the like are taken into consideration. The substitution position of an alkyl group is preferably the para position. The phenyl group substituted with an alkyl group at the para position is preferably a p-hexylphenyl group, a p-heptylphenyl group, a p-octylphenyl group, a p-nonylphenyl group, a p-decylphenyl group, a p-undecylphenyl group, a p-dodecylphenyl group, a p-tridecylphenyl group, a p-tetradecylphenyl group, a p-pentadecylphenyl group, a p-hexadecylphenyl group, a p-2-ethylhexylphenyl group, a p-3,7-dimethyloctylphenyl group, a p-1-propylpentylphenyl group or a p-2-hexyldecylphenyl group, more preferably a p-hexylphenyl group, a p-heptylphenyl group, a p-octylphenyl group, a p-dodecylphenyl group, a p-pentadecylphenyl group, a p-hexadecylphenyl group, a p-2-ethylhexylphenyl group, a p-3,7-dimethyloctylphenyl group or a p-2-hexyldecylphenyl group, particularly preferably a p-dodecylphenyl group, a p-pentadecylphenyl group, a p-2-ethylhexylphenyl group or a p-3,7-dimethyloctylphenyl group.

In the formula (I), the trivalent aromatic heterocyclic group represented by Ar¹ and Ar² denotes an atomic group remaining after removing from an optionally substituted heterocyclic compound having aromaticity three hydrogen atoms on the aromatic ring. The number of carbon atoms of the trivalent aromatic heterocyclic group is usually 2 to 60, preferably 4 to 60, more preferably 4 to 20.

The substituent which the heterocyclic compound having aromaticity optionally has includes, for example, a halogen atom, an amino group, a cyano group and a monovalent organic group. The definitions and specific examples of the halogen atom and the monovalent organic group are the same as the definitions and specific examples of the halogen atom and the monovalent organic group represented by R.

Specific examples of the trivalent aromatic heterocyclic group represented by Ar¹ and Ar² include the following formulae (201) to (301).

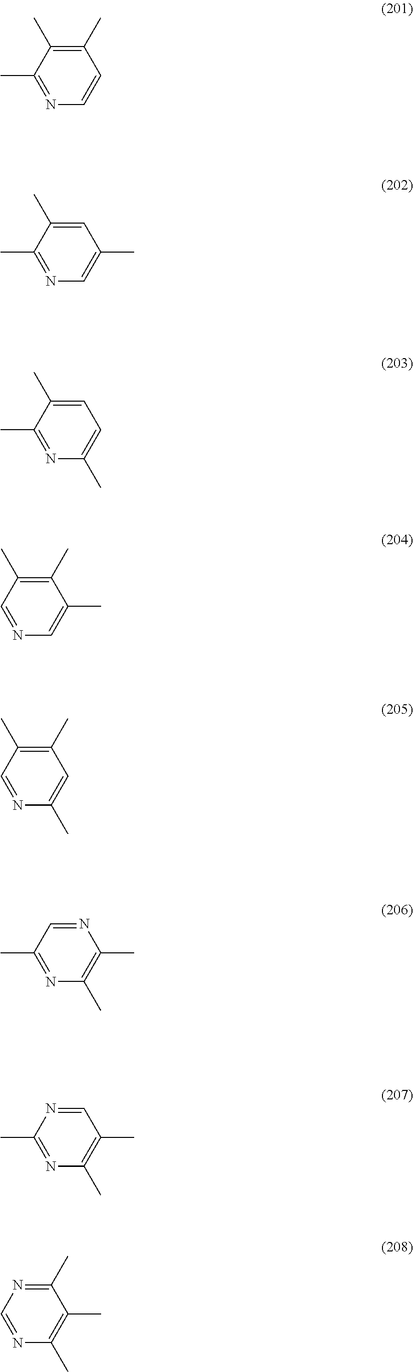

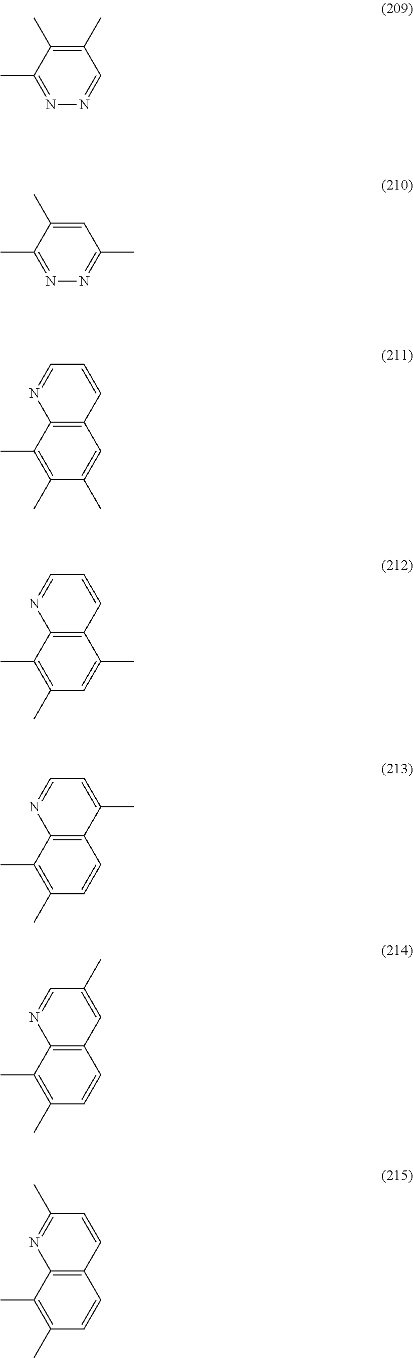

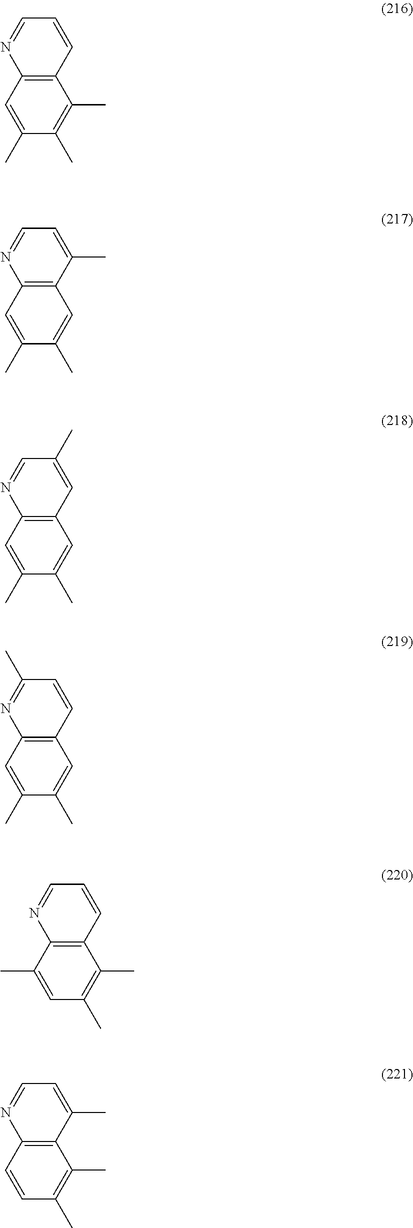

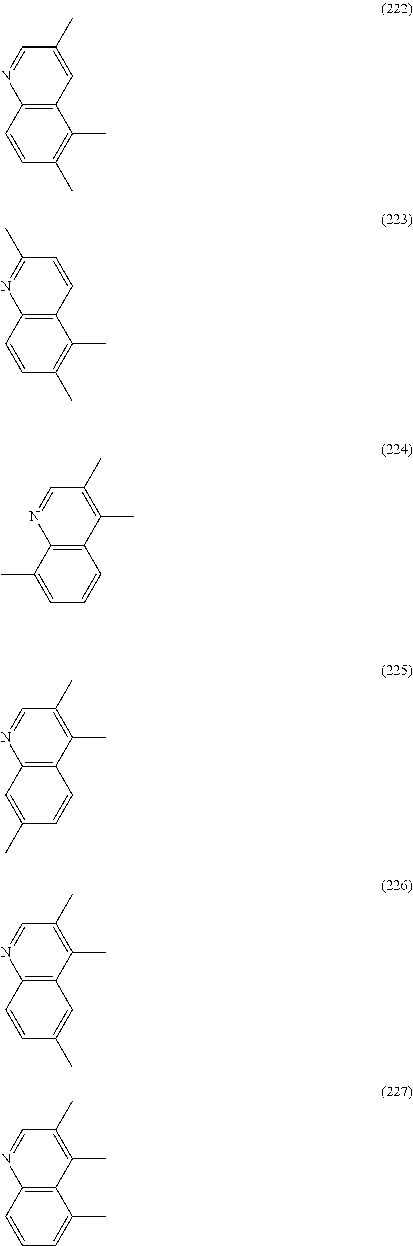

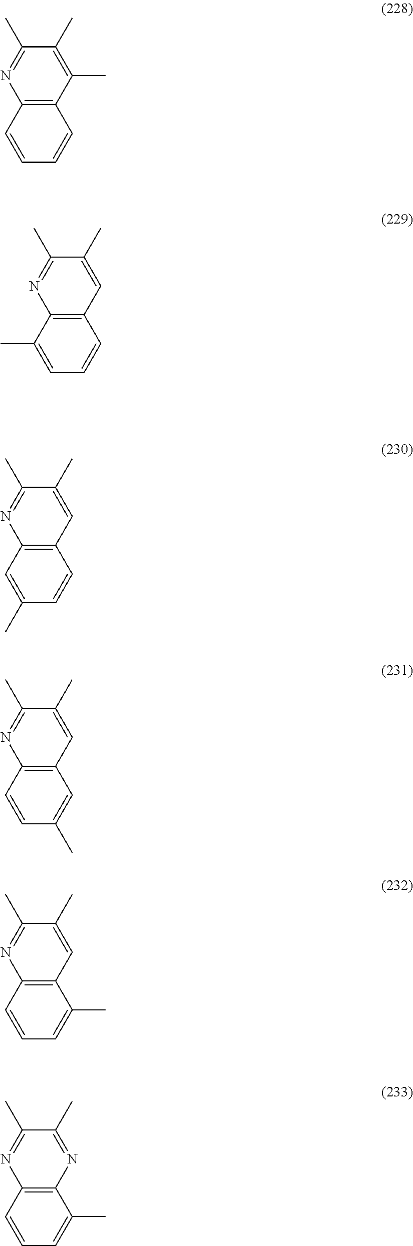

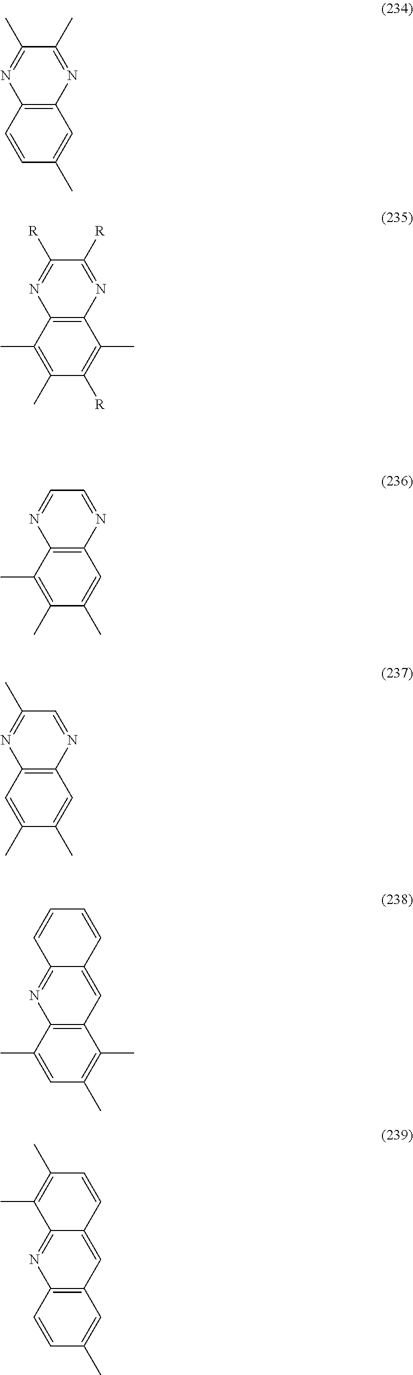

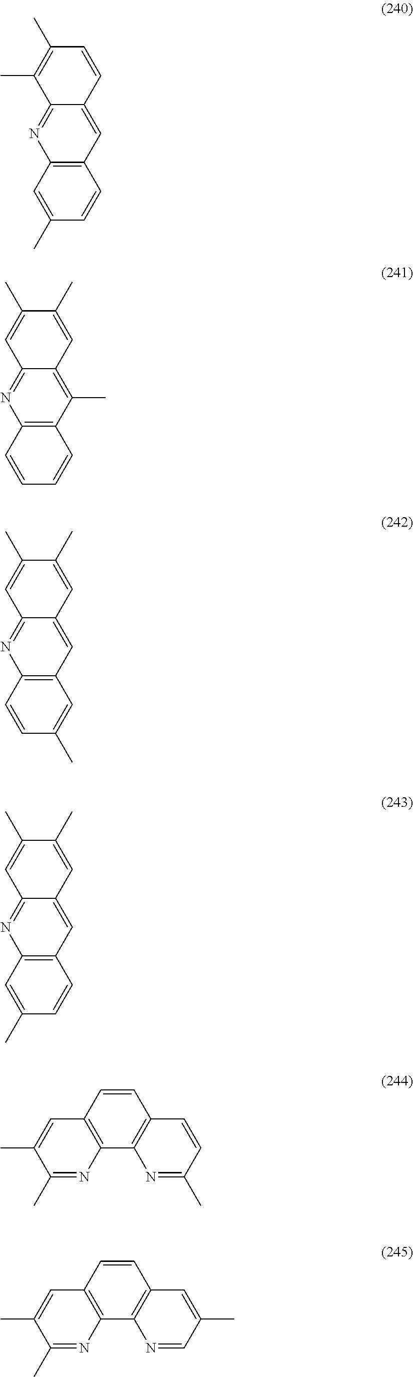

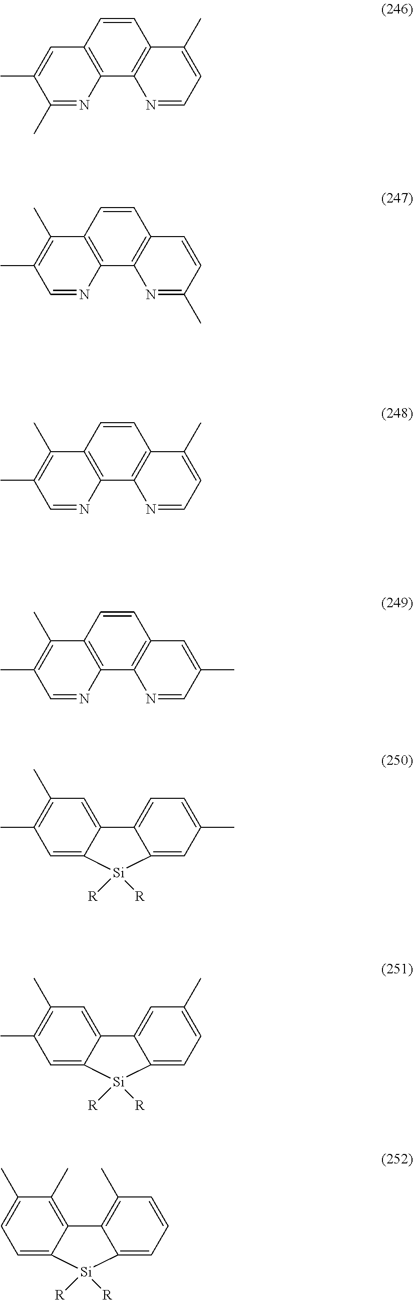

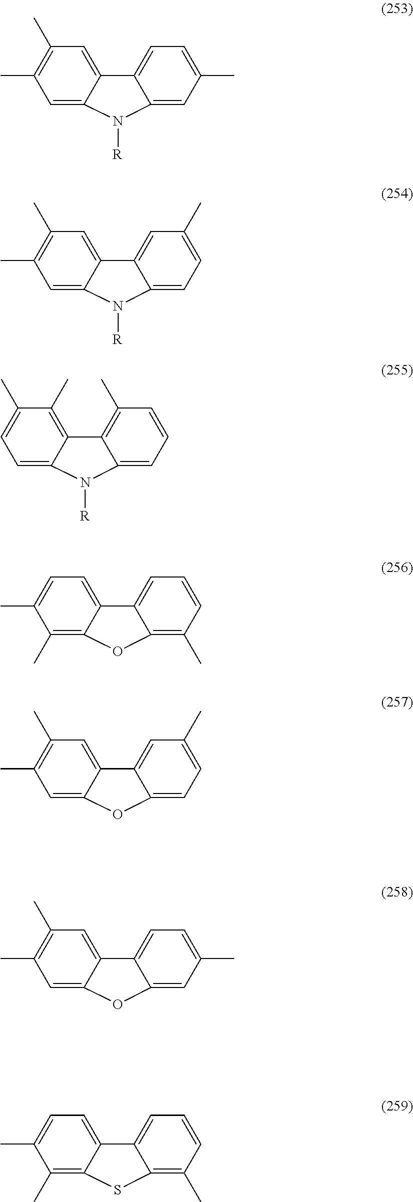

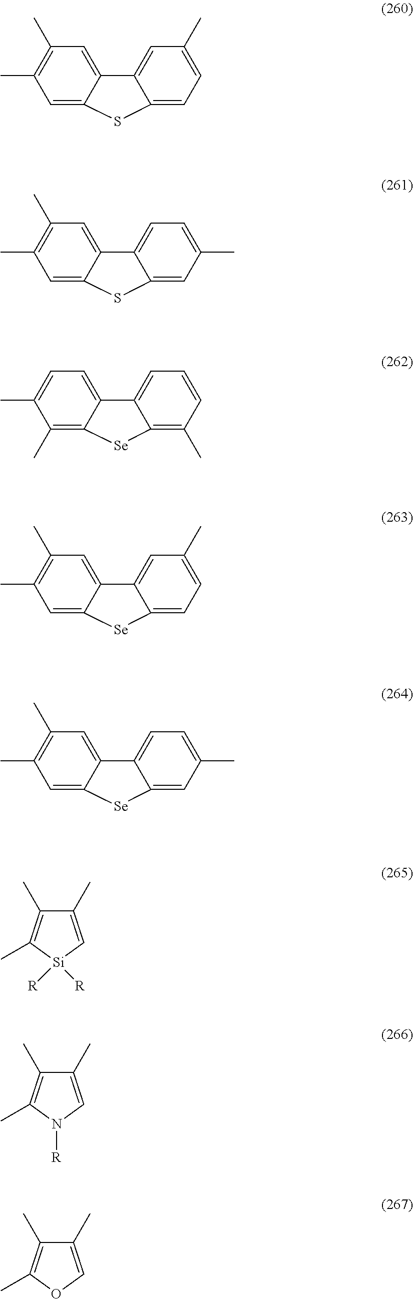

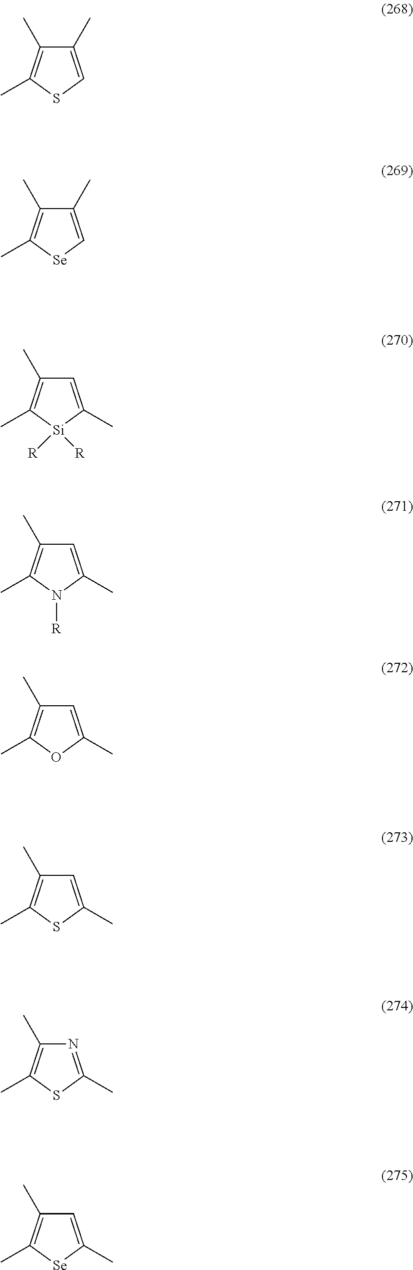

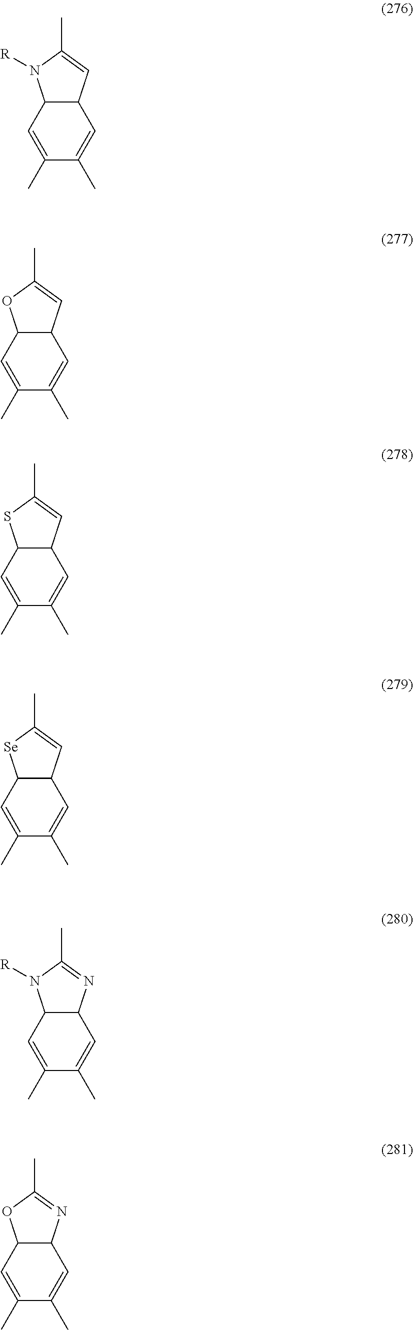

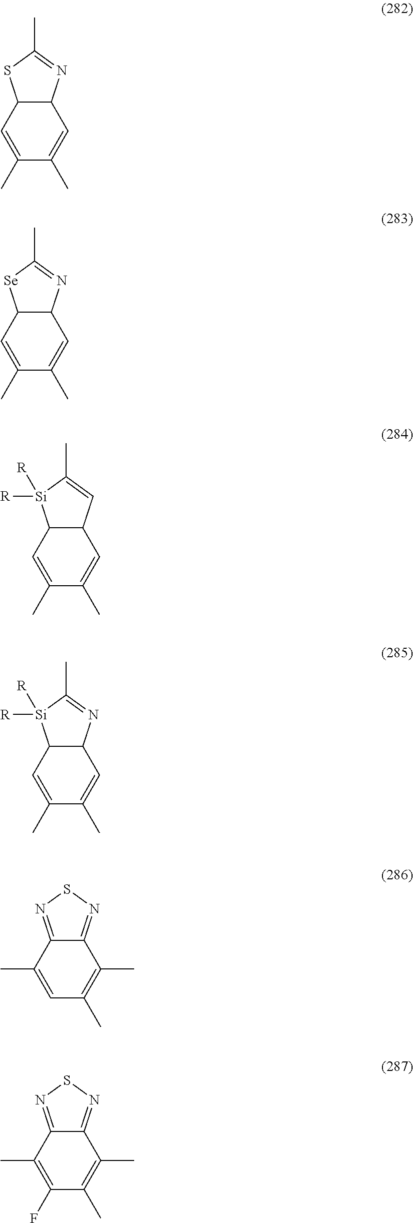

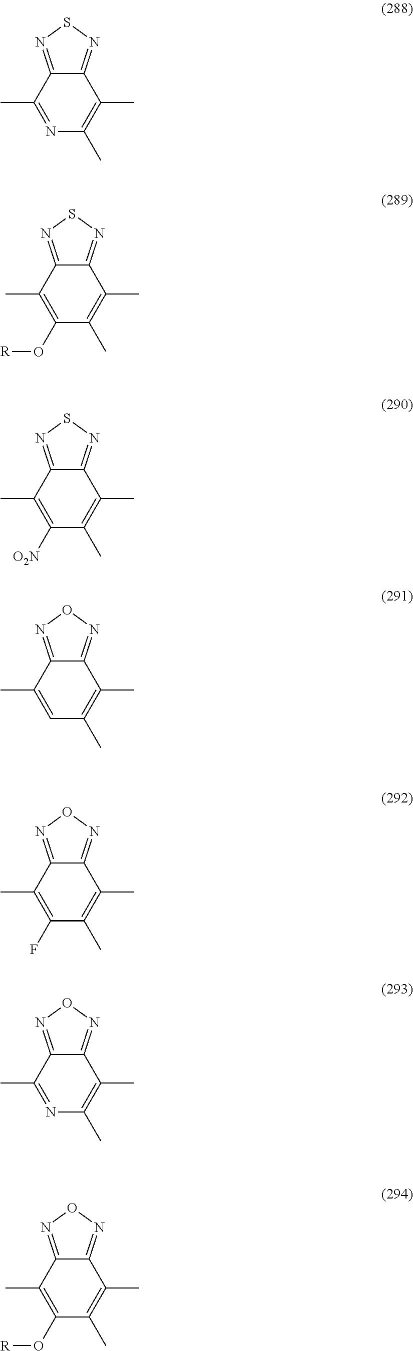

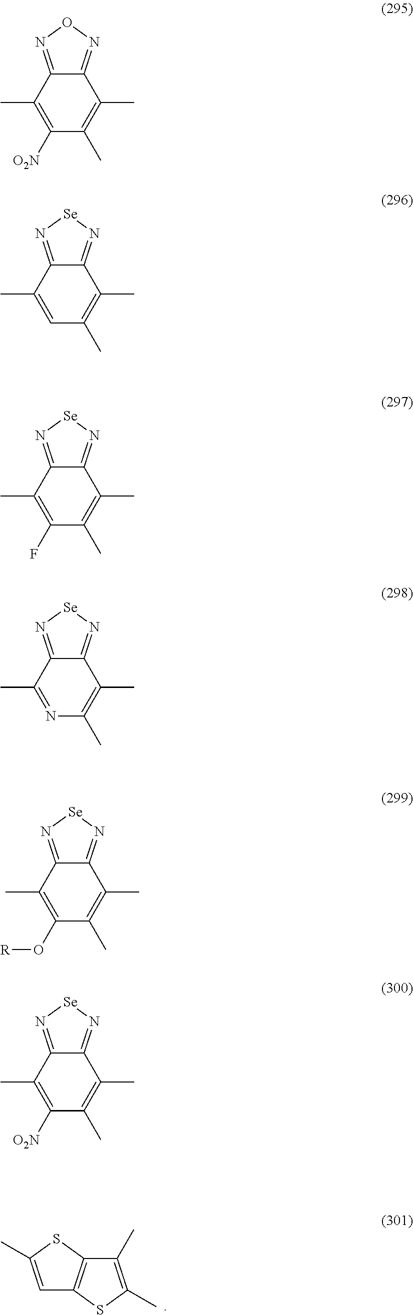

(wherein R represents the same meaning as described above. When a plurality of R are present, they may be the same or different.).

Of trivalent aromatic heterocyclic groups represented by the formula (201) to the formula (301), groups represented by the formula (202), the formula (205), the formula (206), the formula (207), the formula (210), the formula (212), the formula (220), the formula (235), the formula (238), the formula (270), the formula (271), the formula (272), the formula (273), the formula (274), the formula (275), the formula (286), the formula (287), the formula (288), the formula (291), the formula (292), the formula (293), the formula (296) and the formula (301) are preferable, groups represented by the formula (235), the formula (271), the formula (272), the formula (273), the formula (274), the formula (286), the formula (291), the formula (296) and the formula (301) are more preferable, groups represented by the formula (271), the formula (272), the formula (273) and the formula (274) are further preferable, a group represented by the formula (273) is particularly preferable, from the standpoint of easiness of synthesis of a polymer compound.

The constitutional unit represented by the formula (I) is preferably a constitutional unit represented by the following formula (II).

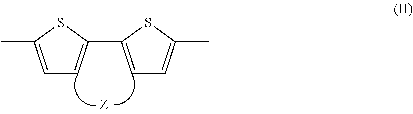

[in the formula (II), Z represents the same meaning as described above.].

The constitutional unit represented by the formula (II) includes, for example, constitutional units represented by the formula (501) to the formula (505).

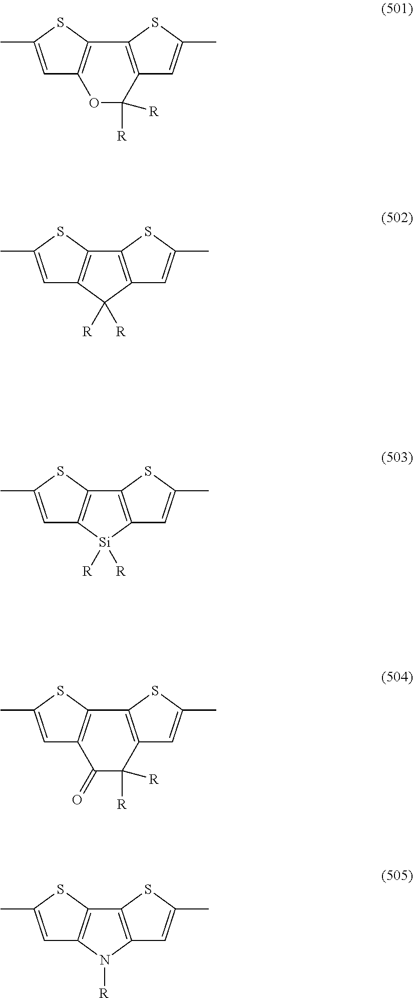

[wherein R represents the same meaning as described above. When two R are present, they may be the same or different.].

Of constitutional units represented by the formula (501) to the formula (505) described above, constitutional units represented by the formula (501), the formula (502), the formula (503) and the formula (504) are preferable, constitutional units represented by the formula (501) and the formula (504) are more preferable, a constitutional unit represented by the formula (501) is particularly preferable, from the standpoint of obtaining the highly efficient photoelectric conversion device of the present invention.

The above-described electron accepting compound may be a low molecular weight compound or a polymer compound. The low molecular weight electron accepting compound includes oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and the like and derivatives thereof, phenanthrene derivatives such as bathocuproine and the like, etc.

The polymer electron accepting compound includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, and the like. Of them, fullerenes and derivatives thereof are especially preferable.

The fullerenes include C₆₀ fullerene, C₇₀ or more fullerenes and carbon nanotubes. The fullerene derivatives include C₆₀ fullerene derivatives and C₇₀ or more fullerene derivatives.

Specific structures of C₆₀ fullerene derivatives include those shown below.

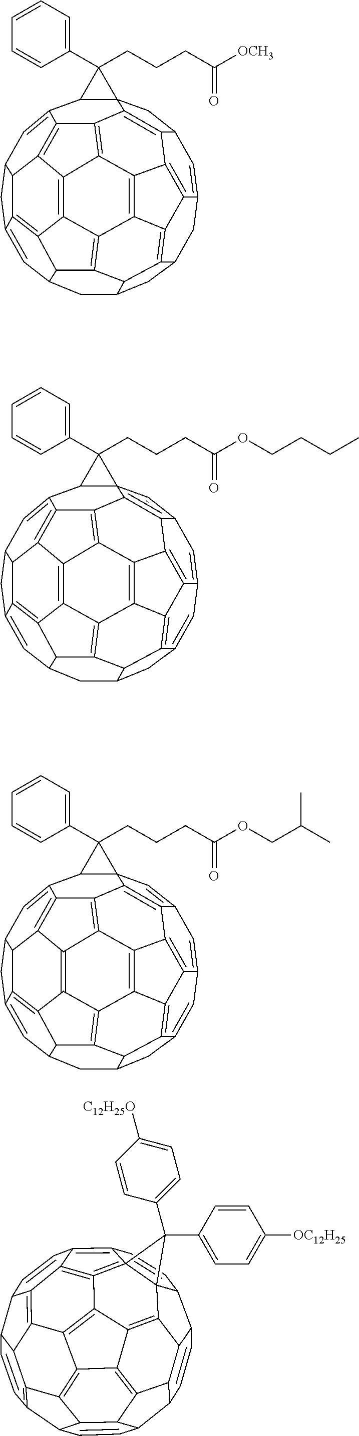

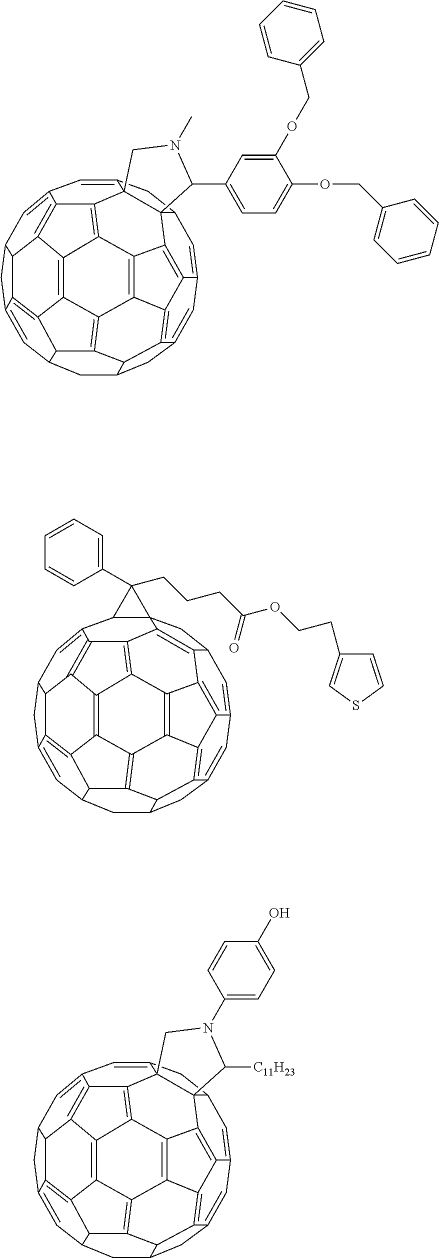

In a constitution wherein the active layer contains an electron accepting compound containing at least one compound selected from the group consisting of fullerenes and derivatives of fullerenes and an electron donating compound, the proportion of fullerenes and derivatives of fullerenes is preferably 10 to 1000 parts by weight, more preferably 50 to 500 parts by weight with respect to 100 parts by weight of the electron donating compound. The photoelectric conversion device preferably has an active layer of a single layer constitution described above, and from the standpoint of much inclusion of the heterojunction interface, more preferably has an active layer of a single layer constitution containing an electron accepting compound containing at least one compound selected from the group consisting of fullerenes and derivatives of fullerenes and an electron donating compound.

Particularly, it is preferable that the active layer contains a polymer compound (preferably, a conjugated polymer compound) and at least one compound selected from the group consisting of fullerenes and derivatives of fullerenes.

The polymer compound used in the active layer includes polyvinylcarbazole and derivatives thereof, polysilane and derivatives thereof, polysiloxane derivatives having an aromatic amine in the side chain or main chain, polyaniline and derivatives thereof, polythiophene and derivatives thereof, polypyrrole and derivatives thereof, polyphenylenevinylene and derivatives thereof, polythienylenevinylene and derivatives thereof, polyfluorene and derivatives thereof, polymer compounds having a constitutional unit represented by the formula (I), and the like, and polymer compounds having a constitutional unit represented by the formula (I) are preferable.

These polymer compounds are preferably conjugated polymer compounds.

The thickness of the active layer is usually 1 nm to 100 μm, preferably 2 nm to 1000 nm, more preferably 5 nm to 500 nm, further preferably 20 nm to 200 nm.

The light absorption peak wavelength of the active layer is preferably 750 to 950 nm, from the standpoint of ensuring transparency in the visible light region and enhancing photoelectric conversion efficiency.

### (Functional Layer)

In the photoelectric conversion device, a functional layer may be disposed between electrodes. As such a functional layer, a functional layer containing an electron transportable material is preferably disposed between an active layer and a cathode. The functional layer is preferably transparent or semitransparent. From the standpoint of ensuring transparency, the film thickness is preferably about 0.1 to 300 nm, preferably 1 to 100 nm.

The functional layer is preferably formed by an application method, and for example, preferably formed by applying an application liquid containing an electron transportable material and a solvent on the surface of a layer on which the functional layer is to be formed. In the present invention, the application liquid includes also dispersion liquids such as an emulsion (emulsified liquid), a suspension (suspended liquid) and the like.

The electron transportable material includes, for example, zinc oxide, titanium oxide, zirconium oxide, tin oxide, indium oxide, ITO (indium tin oxide), FTO (fluorine-doped tin oxide), GZO (gallium-doped zinc oxide), ATO (antimony-doped tin oxide) and AZO (aluminum-doped zinc oxide), and of them, zinc oxide is preferable since high photoelectric conversion efficiency is shown. In forming a functional layer, it preferable that an application liquid containing particulate zinc oxide is applied to form the functional layer. As such an electron transportable material, so-called zinc oxide nanoparticles are preferably used, and it is more preferable to form a functional layer using an electron transportable material composed solely of zinc oxide nanoparticles. The sphere equivalent average particle size of zinc oxide is preferably 1 nm to 1000 nm, more preferably 10 nm to 100 nm. The average particle size is measured by a light scattering method.

By providing a functional layer containing an electron transportable material between a cathode and an active layer, peeling of a cathode can be prevented and efficiency of electron injection from an active layer into a cathode can be enhanced. It is preferable that a functional layer is provided in contact with an active layer and further, it is preferable that a functional layer is provided in contact also with a cathode. By providing a functional layer containing an electron transportable material as described above, peeling of a cathode can be prevented and efficiency of electron injection from an active layer into a cathode can be further enhanced. By providing such a functional layer, a photoelectric conversion device having high reliability and manifesting high photoelectric conversion efficiency can be realized.

The functional layer containing an electron transportable material functions as at least one selected from the group consisting of so called an electron transporting layer and an electron injection layer. By providing such a functional layer, efficiency of injection of electrons into a cathode can be enhanced, injection of holes from an active layer can be prevented, performance of transporting electrons can be enhanced, an active layer can be protected from erosion by an application liquid used in forming a cathode by an application method, and deterioration of an active layer can be suppressed.

It is preferable that the functional layer containing an electron transportable material is constituted of a material having high wettability against an application liquid used in forming a cathode by application. Specifically, it is preferable that the functional layer containing an electron transportable material has higher wettability against the application liquid than wettability of an active layer against an application liquid used in forming a cathode by application. By forming a cathode on such a functional layer by application, an application liquid wets and spreads successfully on the surface of a functional layer in forming a cathode and a cathode having uniform thickness can be formed.

### (Hole Transporting Layer)

The photoelectric conversion device of the present invention may have a hole transporting layer. The hole transporting layer is disposed between an anode and an active layer. It is preferable that the hole transporting layer is transparent or semitransparent, and the thickness thereof is preferably about 0.1 to 300 nm, preferably 1 to 100 nm from the standpoint of ensuring transparency. The material used in a hole transporting layer has abilities to improve smoothness of an electrode and to transport holes, and examples thereof include water-soluble conductive polymers such as polyvinylcarbazole, polysilane, polyethylenedioxythiophene, polystyrene sulfonate and the like, and a hole transporting layer can be formed by applying an aqueous solution of these polymer materials on the surface of an electrode. The material forming a hole transporting layer may advantageously be a water-soluble polymer material. Of them, PEDOT/PSS composed of poly(3,4-ethylenedioxythiophene) (PEDOT) and poly(4-styrene sulfonic acid) (PSS) is preferable since high photoelectric conversion efficiency is shown.

### (Cathode)

The cathode can take the form of a single layer or the form of a laminate of a plurality of layers. The cathode can be formed, for example, by an application method. The application liquid used in forming the cathode by an application method contains the cathode constituent material and a solvent. It is preferable that the cathode contains a polymer compound showing electric conductivity, and it is preferable that the cathode is substantially composed of a polymer compound showing electric conductivity. The cathode constituent materials include organic materials such as polyaniline and derivatives thereof, polythiophene and derivatives thereof, polypyrrole and derivatives thereof, and the like. For example, a transparent or semi transparent electrode obtained by adjusting the thickness of the film constituting the cathode to a thickness around which light can pass is used as the cathode.

It is preferable that the cathode contains at least one selected from the group consisting of polythiophene and polythiophene derivatives. It is preferable that the cathode contains at least one selected from the group consisting of polyaniline and polyaniline derivatives.

Specific examples of polythiophene and derivatives thereof include compounds containing one or more units among a plurality of structural formulae shown below as a repeating unit.

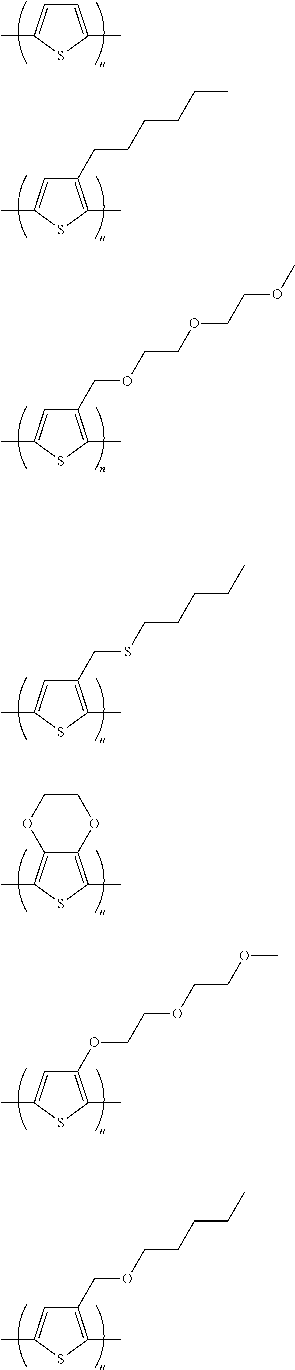

(wherein n represents an integer of 1 or more.)

Specific examples of polypyrrole and derivatives thereof include compounds containing one or more units among a plurality of structural formulae shown below as a repeating unit.

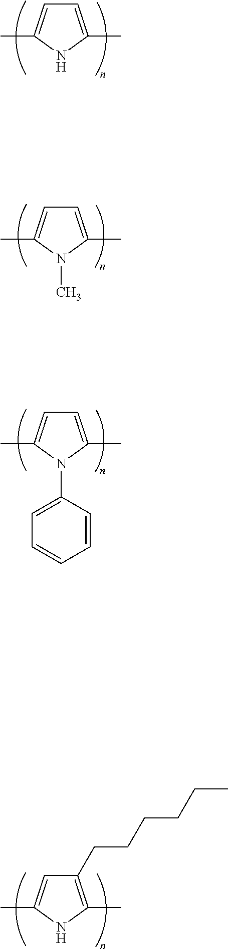

(wherein n represents an integer of 1 or more.)

Specific examples of polyaniline and derivatives thereof include compounds containing one or more units among a plurality of structural formulae shown below as a repeating unit.

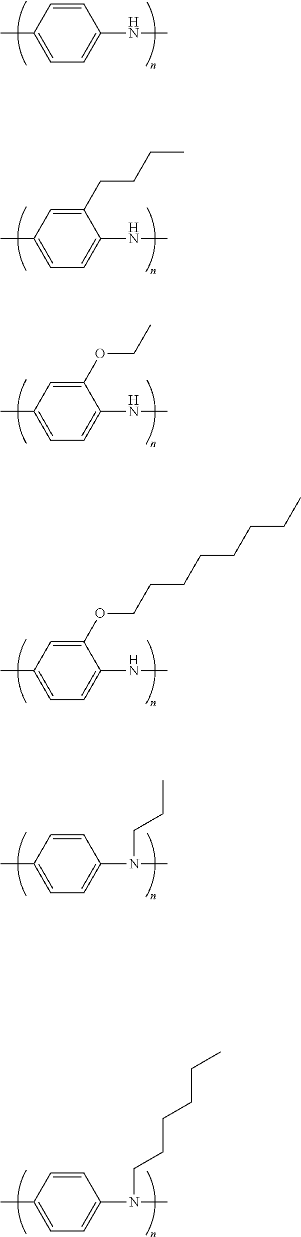

(wherein n represents an integer of 1 or more.)

Of the above-described cathode constituent materials, PEDOT/PSS composed of poly(3,4-ethylenedioxythiophene) (PEDOT) and poly(4-styrene sulfonic acid) (PSS) is suitable used as the cathode constituent material since it has high photoelectric conversion efficiency.

The cathode may be formed by an application method using an emulsion (emulsified liquid) or a suspension (suspended liquid) containing nanoparticles of an electrically conductive substance, nanowires of an electrically conductive substance or nanotubes of an electrically conductive substance, a dispersion such as a metal paste and the like, a low melting metal in molten state and the like, the application liquid not being limited to an application liquid containing the above-described organic materials. The electrically conductive substance includes metals such as gold, silver and the like, oxides (metal oxide) such as ITO (indium tin oxide) and the like, carbon nanotubes, and the like. The cathode may be constituted solely of nanoparticles or nanofibers of an electrically conductive substance, however, the cathode may also have a constitution in which nanoparticles or nanofibers of an electrically conductive substance are dispersed and placed in a given medium such as an electrically conductive polymer and the like, as disclosed in Japanese Patent Application National Publication No. 2010-525526.

### (Sealing Substrate)

The sealing substrate includes, for example, a glass substrate, a plastic substrate, a polymer film and the like. As the sealing substrate, a substrate showing high light permeability is suitably used.

### (Reflection Plate)

In the reflection plate used in the present invention, the average transmittance of light in a wavelength range of from 400 to 700 nm is 70% or more. It is preferable that the average transmittance of light in a wavelength range of from 400 to 650 nm is 80% or more. The average transmittance is a value obtained by averaging transmittances of light measured every 1 nm in a wavelength range of from 400 to 700 nm or a wavelength range of from 400 to 650 nm.

In the reflection plate used in the present invention, the active layer has an average reflectance of 50% or more of light in a region of ±150 nm of the light absorption peak wavelength. The average reflectance of the light is preferably 60% or more, more preferably 70% or more, further preferably 80% or more. The average reflectance is a value obtained by averaging reflectances of light measured every 1 nm in a region of ±150 nm of the light absorption peak wavelength. As the reflection plate in the present invention, for example, a near-infrared reflection film composed of a dielectric multi-layered film can be used. The dielectric multi-layered film has a structure in which low refractive index layers and high refractive index layers are laminated alternately. The difference in refractive index between the high refractive index layer and the low refractive index layer is preferably 0.5 or more, more preferably 1.0 or more. When the difference in refractive index is 1.0 or more, cuttable width of wavelength in the near-infrared region broadens and a filter more excellent in near-infrared cutting performance is obtained.

### <High Refractive Index Layer>

The refractive index of the material constituting the high refractive index layer is usually 1.6 or less, preferably 1.2 to 1.6. As such a material, for example, silica (SiO₂), alumina, lanthanum fluoride, magnesium fluoride, aluminum sodium hexafluoride and the like are listed, and silica is preferable.

### <Low Refractive Index Layer>

The refractive index of the material constituting the low refractive index layer is usually 1.7 or more, preferably 1.7 or more and 2.5 or less. As such a material, one or more materials selected from the group including, for example, titanium oxide (titania (TiO₂)), zirconium oxide, tantalum pentoxide, niobium pentoxide, lanthanum oxide, yttrium oxide, zinc oxide, zinc sulfide, indium oxide and the like, are listed. Preferable are one or more materials selected from the group consisting of titania (TiO₂), ITO (tin-doped indium oxide) and ATO (antimony-doped tin oxide). Particularly, one or more materials selected from the group consisting of ITO (tin-doped indium oxide) and ATO (antimony-doped tin oxide) can be used.

Further, in the reflection plate used in the present invention, the average reflectance of light in a wavelength range of from 850 to 1100 nm is 50% or more from the standpoint of imparting near-infrared cutting performance. The average reflectance is preferably 60% or more, more preferably 70% or more, further preferably 80% or more. The average reflectance is a value obtained by averaging the reflectances of light measured every 1 nm in a wavelength range of from 850 to 1100 nm.

The position of forming the reflection plate is not limited to just above a cathode or an anode, and the reflection plate may be formed inside a sealing substrate or outside a sealing substrate, and it may also be permissible that the reflection plate is formed on a novel substrate and the substrate is pasted.

### (Measurement of Reflectance and Transmittance)

As the apparatus for measuring reflectance and transmittance, use is made of a spectrophotometer operating in ultraviolet, visible and near-infrared wavelength ranges (for example, manufactured by JASCO Corporation, ultraviolet visible near-infrared spectrophotometer JASCO-V670). When JASCO-V670 is used, the measurable wavelength range is 200 to 2500 nm, thus, measurement is conducted in this wavelength range.

For measurement of the absorption spectrum of a film containing a polymer compound, for example, an ultraviolet visible near-infrared spectrophotometer manufactured by JASCO Corporation (trade name: V670) is used. When V670 is used, the absorption spectrum can be measured in a wavelength range of 300 nm to 2500 nm.

First, a film containing a polymer compound is formed on a substrate (for example, a quartz substrate, a glass substrate) by applying a solution containing a polymer compound or a melted body containing a polymer compound.

Next, the absorption spectrum of the substrate and the absorption spectrum of a laminate composed of the film and the substrate are measured.

The absorption spectrum of the film is obtained by subtracting the absorption spectrum of the substrate from the absorption spectrum of the laminate.

The ordinate and the abscissa of the absorption spectrum show the absorbance and the wavelength, respectively. It is desirable to control the thickness of the film so that the maximum absorbance is 0.3 to 2.

### <2> Production Method of Photoelectric Conversion Device

The production method of the photoelectric conversion device of the present invention will be illustrated using a photoelectric conversion device in which the first electrode is an anode and the second electrode is a cathode, by way of example.

This photoelectric conversion device can be produced by forming an anode on a supporting substrate, forming an active layer on the above-described anode, forming a cathode on the above-described active layer for example by an application method, then, pasting a reflection plate onto the cathode.

### <Anode Formation Step>

The anode is formed by forming a film of the above-described anode material on the above-described supporting substrate by a vacuum vapor deposition method, a sputtering method, an ion plating method, a plating method and the like. The anode may also be formed by an application method using an application liquid containing an organic material such as polyaniline and derivatives thereof, polythiophene and derivatives thereof and the like, a metal ink, a metal paste, a low melting metal in molten state, and the like.

### <Active Layer Formation Step>

The method of forming the active layer is not particularly restricted, and it is preferable to form the active layer by an application method from the standpoint of simplification of the production step. The active layer can be formed by an application method using an application liquid containing the above-described active layer constituent materials and a solvent, and for example, can be formed by an application method using an application liquid containing at least one compound selected from the group consisting of conjugated polymer compounds and fullerenes and derivatives of fullerenes, and a solvent.

The solvent includes, for example, hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexxane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, etc. The application liquid used in the present invention may contain two or more kinds of solvents.

The method of applying an application liquid containing the active layer constituent material includes application methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an Inkjet printing method, a dispenser printing method, a nozzle coat method, a capillary coat method and the like, and of them, a spin coat method, a flexo printing method, an inkjet printing method and a dispenser printing method are preferable.

### <Functional Layer Formation Step>

As described above, it is preferable to form a functional layer containing an electron transportable material between an active layer and a cathode. That is, it is preferable to form a functional layer by applying an application liquid containing the above-described electron transportable material on an active layer, after formation of the active layer and before formation of the cathode.

When a functional layer containing an electron transportable material is disposed in contact with an active layer, a functional layer is formed by applying the above-described application liquid on the surface of an active layer. In forming a functional layer, it is preferable to use an application liquid imparting little damage on the layer on which the application liquid is to be coated (active layer and the like), and specifically, it is preferable to use an application liquid poorly dissolving the layer on which the application liquid is to be coated (active layer and the like). That is, when an application liquid used in forming a cathode is applied on an active layer, it is preferable to form a functional layer using an application liquid giving smaller damage to the active layer than damage to the active layer by the application liquid. Specifically, it is preferable to form a functional layer using an application liquid showing poorer dissolvability for the active layer than that of an application liquid used in forming a cathode.

The application liquid used in applying and forming a functional layer contains a solvent and the above-described electron transportable material. The solvent of the above-described application liquid includes water, alcohols and the like, and specific examples of the alcohol include methanol, ethanol, isopropanol, butanol, ethylene glycol, propylene glycol, butoxyethanol, methoxybutanol and the like. The application liquid used in the present invention may contain two or more kinds of solvents, and may contain two or more of the solvents exemplified above.

### <Cathode Formation Step>

The cathode is formed on the surface of an active layer or a functional layer, for example, by an application method. Specifically, the cathode is formed by applying an application liquid containing a solvent and the above-described cathode constituent material on the surface of a light emitting layer or a functional layer. The solvent of the application liquid used in forming the cathode includes, for example, hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexxane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like, water, alcohols and the like. Specific examples of the alcohol include methanol, ethanol, isopropanol, butanol, ethylene glycol, propylene glycol, butoxyethanol, methoxybutanol and the like. The application liquid used in the present invention may contain two or more kinds of solvents, and may contain two or more of the solvents exemplified above.

When forming a cathode using an application liquid imparting damage on an active layer and a functional layer, it maybe permissible for example that the cathode has a two-layer constitution and the first film is formed using an application liquid not imparting damage on a light emitting layer and a functional layer, then, the second film is formed using an application liquid possibly imparting damage on a light emitting layer and a functional layer. By adopting the cathode having a two-layer constitution as described above, it is possible to suppress damage imparted on a light emitting layer and a functional layer since the first film functions as a protective layer even if the second film is formed using an application liquid possibly imparting damage on a light emitting layer and a functional layer. For example, when a cathode is formed on a functional layer composed of zinc oxide, it may be permissible that the first film is formed using a neutral application liquid, subsequently, the second film is formed using an acidic solution, thereby forming a cathode having a two-layer constitution, since the functional layer composed of zinc oxide is liable to be damaged by an acidic solution.

In the photoelectric conversion device of the present invention, when a transparent or semi-transparent electrode is irradiated with light such as solar light and the like, photovoltaic power is generated between electrodes, and the device can be operated as an organic film solar battery.

A plurality of organic film solar batteries can be integrated, and used as an organic film solar battery module.

In the photoelectric conversion device of the present invention, when a transparent or semi-transparent electrode is irradiated with light under condition of application of voltage between electrodes, photocurrent flows, and the device can be operated as an organic optical sensor. A plurality of organic optical sensors can be integrated, and used as an organic image sensor.

When a cathode and an anode are constituted of a transparent or semitransparent electrode, a photoelectric conversion device showing light permeability can be constituted. Such a photoelectric conversion device has a merit that a parallel or serial multi-junction device can be easily constituted by superimposing the device on an opaque photoelectric conversion derive or a photoelectric conversion device showing light permeability.

### <Production Step of Reflection Plate>

The reflection plate is formed, for example, by forming a near-infrared reflection film composed of a dielectric multi-layered film described above on a glass substrate or the like by a vacuum vapor deposition method, a sputtering method, an ion plating method, a plating method and the like.

### EXAMPLES

Examples are shown below for illustrating the present invention further in detail, but the present invention is not limited to them.

### Synthesis Example 1

### (Synthesis of Polymer Compound A)

A polymer compound A constituted of the following constitutional units was synthesized according to a method described in Example 1 of International Publication WO2013/051676A1 and used as the polymer compound having a constitutional unit represented by the formula (I) of the present invention.

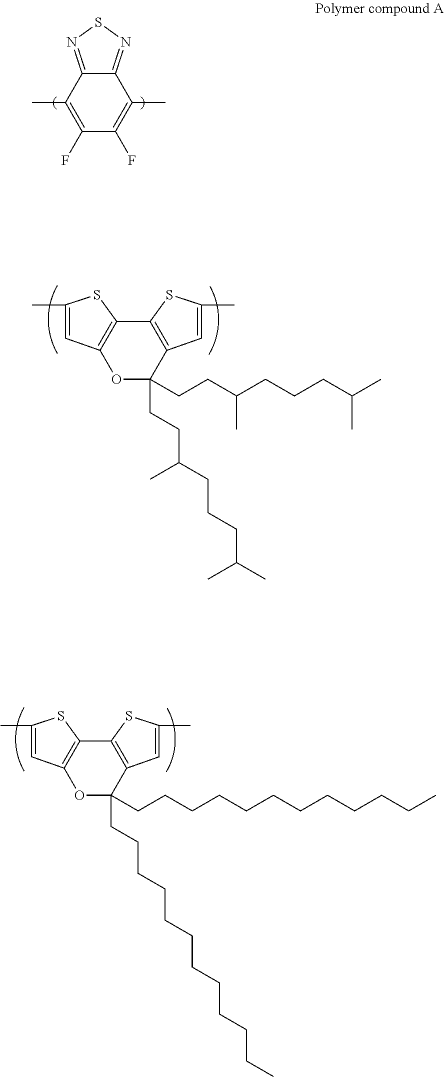

### (Preparation of Ink 1)

The polymer compound A and fullerene C60PCBM (phenyl C61-butyric acid methyl ester, manufactured by Frontier Carbon Corporation) were dissolved in tetralin, to prepare an ink 1. The ratio of the weight of C60PCBM with respect to the weight of the polymer compound A was 2. In the ink 1, the sum of the weight of the polymer compound A and the weight of C60PCBM was 1.5 wt % with respect to the weight of the ink 1.

### Example 1

### (Fabrication and Evaluation of Organic Film Solar Battery)

A glass substrate carrying thereon an ITO film functioning as an anode of a solar battery was prepared. The ITO film was one firmed by a sputtering method, and its thickness was 150 nm. This glass substrate was subjected to an ozone uv treatment, thereby surface-treating the ITO film. Next, a PEDOT:PSS solution (CleviosP VP AI4083, manufactured by H. C. Starck) was applied onto the ITO film by spin coating, and heated in atmospheric air at 120° C. for 10 minutes, to form a hole transporting layer having a thickness of 35 nm. On this hole transporting layer, the above-described ink 1 was applied by spin coating, to form an active layer (thickness: about 120 nm).

Simultaneously, an active layer is formed also on the glass substrate, and the absorption spectrum thereof was measured using a spectrophotometer (ultraviolet visible near-infrared spectrophotometer JASCO-V670, manufactured by JASCO Corporation). The absorption peak wavelength was 810 nm.

Next, 1 part by weight of a 45 wt % isopropanol dispersion (HTD-711Z, manufactured by TAYCA Corporation) of zinc oxide nano particles (particle diameter: 20 to 30 nm) and 5 parts by weight of isopropanol containing sodium acetylacetonate dissolved at a proportion of 1 wt % were mixed, to prepare an application liquid. This application liquid was applied with a film thickness of 45 nm on the light emitting layer by spin coating, and the film was dried, to form a functional layer insoluble in a water solvent.

Next, a wire-like conductor dispersion using a water solvent (ClearOhm (registered trademark) Ink-N AQ: manufactured by Cambrios Technologies Corporation) was applied by a spin coater and dried, to obtain a cathode composed of a conductive wire layer having a thickness of 120 nm. Thereafter, an UV curable sealant was applied to peripheral parts and a glass substrate was pasted, then, irradiation with UV light was performed, to attain sealing.

Next, an IR cut filter (IRC2, manufactured by CERATEC JAPAN Co., Ltd.) as a reflection plate was pasted to the external side of the sealed substrate using a highly transparent self-adhesive film (CEF0806, manufactured by 3M), to obtain an organic film solar battery. The transmission spectrum of the resultant organic film solar battery was measured using a spectrophotometer (ultraviolet visible near-infrared spectrophotometer JASCO-V670, manufactured by JASCO Corporation). The average transmittance in a wavelength range of from 400 to 700 nm was 45%.

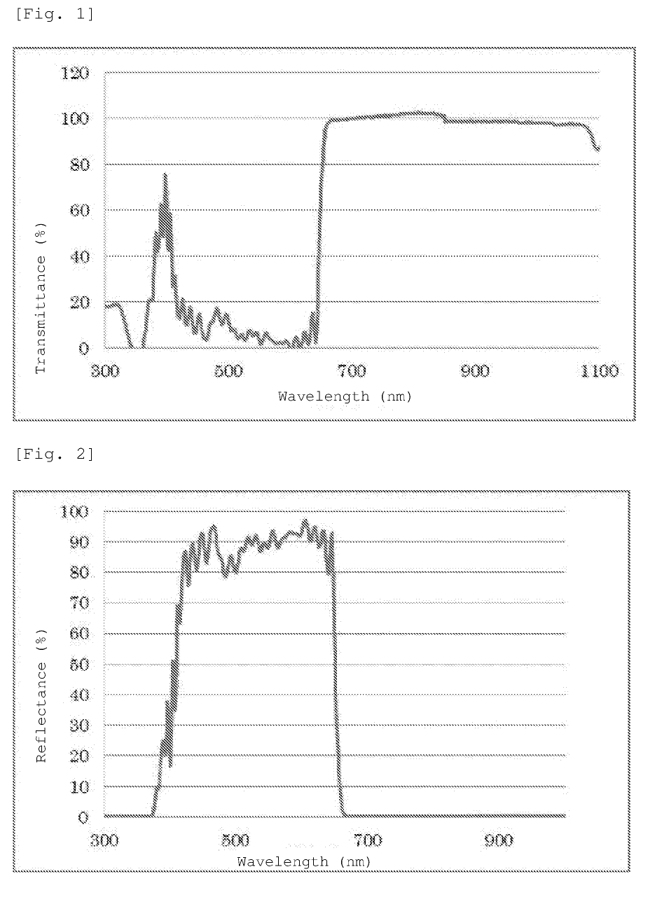

The reflection and transmission spectra of the used IR cut filter were measured using a spectrophotometer (ultraviolet visible near-infrared spectrophotometer JASCO-V670, manufactured by JASCO Corporation) and the results of the transmittance are shown in FIG. 1. The results of the reflectance are shown in FIG. 2. The average transmittance in a wavelength range of from 400 to 700 nm was 72% and the average reflectance in a wavelength range of from 660 to 960 nm was 100%. The average reflectance of light in a wavelength range of from 850 to 1100 nm was 98%. The average transmittance in a wavelength range of from 400 to 650 nm was 86%.

The shape of the resultant organic film solar battery was 10 mm×10 mm regular tetragon. The resultant organic film solar battery was irradiated with constant light using Solar Simulator (manufactured by Bunkoukeiki Co., Ltd., tradename: OTENTO-SUNII: AM 1.5G filter, irradiance: 100 mW/cm²), and generating current and voltage were measured, to determine photoelectric conversion efficiency. The photoelectric conversion efficiency was 4.58%.

### Comparative Example 1

The same organic film solar battery as in Example 1 was fabricated, excepting that no IR cut filter was pasted to the external side of the sealed substrate.

The resultant organic film solar battery was irradiated with constant light using Solar Simulator (manufactured by Bunkoukeiki Co., Ltd., trade name: OTENTO-SUNII: AM 1.5G filter, irradiance: 100 mW/cm²) and generating current and voltage were measured, to determine photoelectric conversion efficiency. The photoelectric conversion efficiency was 3.89%.

### INDUSTRIAL APPLICABILITY

According to the present invention, a highly efficient photoelectric conversion device is provided.

1. A photoelectric conversion device comprising a supporting substrate, an electrode, an active layer, an electrode and a reflection plate laminated in this order and having an average transmittance of 10% or more of light in a wavelength range of from 400 to 700 nm, wherein the reflection plate has an average transmittance of 70% or more of light in a wavelength range of from 400 to 700 nm and the active layer has an average reflectance of 50% or more of light in a region of ±150 nm of the light absorption peak wavelength.

2. The photoelectric conversion device according to claim 1, wherein the reflection plate further has an average reflectance of 50% or more of light in a wavelength range of from 850 to 1100 nm.

3. The photoelectric conversion device according to claim 1, wherein the active layer contains a polymer compound.

4. The photoelectric conversion device according to claim 3, wherein the active layer containing the polymer compound has a light absorption peak wavelength of 750 to 850 nm.

5. The photoelectric conversion device according to claim 3, wherein the polymer compound is a polymer compound having a constitutional unit represented by the formula (I): 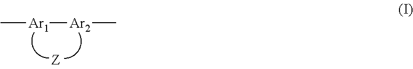
[in the formula (I), Z represents a group represented by any one of the following formulae (Z-1) to (Z-7). Ar¹ and Ar² may be the same or different and represent a trivalent aromatic heterocyclic group.] 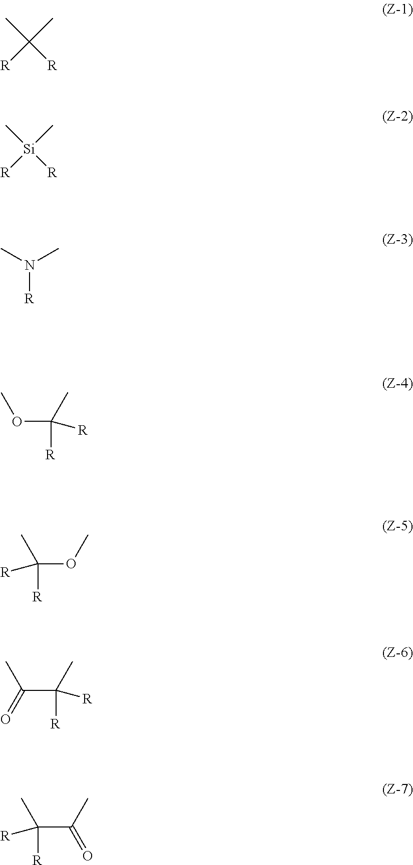
[in the formula (Z-1) to the formula (Z-7), R represents a hydrogen atom, a halogen atom, an amino group, a cyano group or a monovalent organic group. When two R are present, they may be the same or different.].

6. The photoelectric conversion device according to claim 5, wherein the constitutional unit represented by the formula (I) is a constitutional unit represented by the following formula (II): 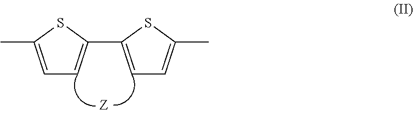
[in the formula (II), Z represents the same meaning as described above.].

7. The photoelectric conversion device according to claim 5, wherein Z is a group represented by any one of the formulae (Z-4) to (Z-7).

8. The photoelectric conversion device according to claim 5, wherein the constitutional unit represented by the formula (I) is a constitutional unit represented by the following formula (III): 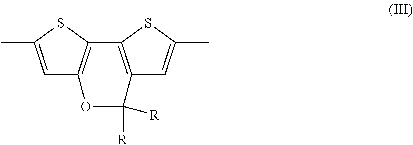
[in the formula (III), two R may be the same or different and represent the same meaning as described above.].

9. A solar battery module comprising the photoelectric conversion device according to claim 1.
